(19) United States
(12) Patent Application Publication
(10) Pub. No.: US 2010/0133671 A1
(43) Pub. Date: Jun. 3, 2010

(54) Flip-chip package structure and the die attach method thereof

(76) Inventor: Chung Hsing Tzu, ChungHe City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/457,349

(22) Filed: Jun. 9, 2009

Related U.S. Application Data
(60) Provisional application No. 61/119,046, filed on Dec. 2, 2008.

(51) Int. Cl. H01L 23/495; H01L 23/498; H01L 21/50

(52) U.S. Cl. 257/676; 257/692; 438/120; 438/106; 257/E23.07; 257/E23.031; 257/E21.499

(57) ABSTRACT

A flip-chip package structure comprises a carrier, a block bump, and a die. The carrier is a lead frame or substrate that comprises a lead pattern side, and an electrode pin is disposed on the lead pattern side. The die comprises an active side, and a bond pad is disposed on the active side. The block bump is bonded to the electrode pin; the bond pad of the die is attached on the carrier through the block bump, so that the die and the carrier joint together to form the flip chip package structure. Besides, the block bump is formed by the wedge bonding, and therefore in bumping size and shapes can easily form larger bump, which will increase the compactness between the die and the carrier.

### CROSS REFERENCE TO RELATED APPLICATIONS

This application claims priority of U.S. Provisional Application No. 61/119,046 filed on 2 Dec. 2008 under 35 U.S.C. §119(e), the entire contents of which are all hereby incorporated by reference.

### FIELD OF THE INVENTION

The present invention relates to a flip chip package technique for attaching a die on a carrier.

### BACKGROUND OF THE INVENTION

For semiconductor industry field, the flip-chip technology is very popular in every kind of package devices, which is advantageous in reducing the package size and shortening of the signal conduction path.

Referring to FIG. 1, there is shown a schematic diagram of the flip chip package structure of the prior art.

The flip-chip package structure 100 comprises a carrier 11, a ball bump 13, and a die 15. Wherein the carrier 11 is a lead frame or structure that comprises a lead pattern side 112, and an electrode 111 is disposed on the lead pattern side 112. Besides, the ball bump 13 is bonded to the electrode 111 of the carrier 11 by a wire ball bonding technology.

The die 15 comprises an active side 152, and a bond pad 151 is disposed on the active side 152. The bond pad 151 of the die 15 will attach on the carrier 11 through the ball bump 13, so that the die 15 and the carrier 11 joint together to form the flip chip package structure 100.

Regarding the flip-chip structure 100 of the prior art, the die 15 is attached on the carrier 11 through the ball bump 13, the ball bump 13 is formed by a wire ball bonding technology, and therefore in bumping size and shapes can only be constrained to a small round ball. So the contact area between the die 15 and the carrier 11 will be smaller, which makes the die 15 easily disconnection form the carrier 11, and further limits electrical performance and thermal dissipation performance when a lower contact resistance and a more efficient thermal dissipation are needed.

### SUMMARY OF THE INVENTION

It is the primary objective of the present invention to provide a flip-chip package structure and the die attach method thereof, in which the die is attached on the carrier through a block bump of larger size, so as to increase the compactness between the die and the carrier.

It is the secondary objective of the present invention to provide a flip-chip package structure and the die attach method thereof, the block bump is easily formed into the larger sizes by a wedge bonding, which reduce the contact resistance and increase the contact area between the die and the carrier, so as to enhance the electrical performance and thermal dissipation performance of the flip-chip package structure.

To achieve the above mentioned and other objectives, the present invention provides a flip chip package structure, comprising: a carrier; a block bump formed on the carrier; and a die with a bond pad disposed thereon, wherein the bond pad of the die is bonded to the block bump of the carrier.

The present invention further provides a flip chip package structure, comprising: a carrier comprising a lead pattern side, and a first electrode pin and a second electrode pin disposed on the lead pattern side; a first block bump and a second block bump respectively bonded to the first electrode pin and the second electrode pin by ultrasonic bonding or wedge bonding such that metal diffusion is happened between the bumps and the electrode pins; and a die comprising an active side and a backside, and a first bond pad and a second bond pad disposed on the active side; wherein the first bond pad and the second bond pad of the die are respectively bonded to the first block bump and the second block bump of the carrier.

The present invention further provides a die attach method of a flip chip package structure, comprising: providing a carrier with a electrode and a die with a bond pad ; forming a block bump on the electrode; and bonding the bond pad of the die to the block bump such that the die is attached to the carrier.

### BRIEF DESCRIPTION OF THE DRAWINGS

FIG. 1 shows a schematic diagram of the flip chip package structure of the prior art.

FIG. 2A to 2D show a schematic diagram of a flip chip packaging die attach process of a preferred embodiment of the present invention.

FIG. 3 shows a schematic diagram of the flip chip package structure of an embodiment of the present invention.

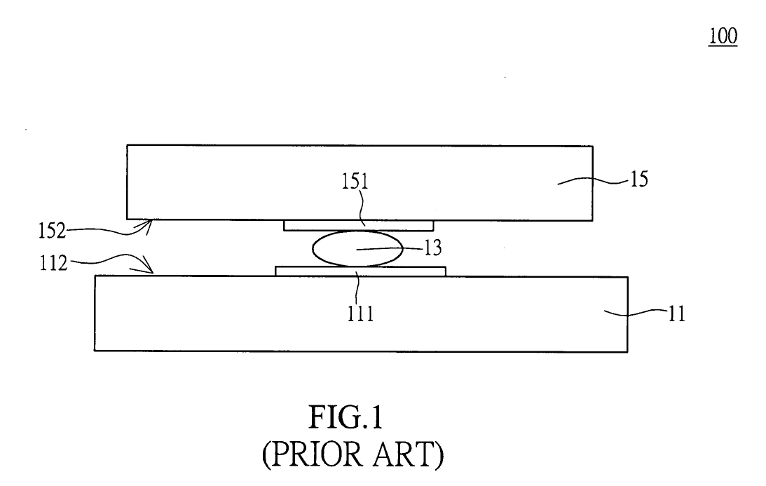

### DETAILED DESCRIPTION OF THE INVENTION

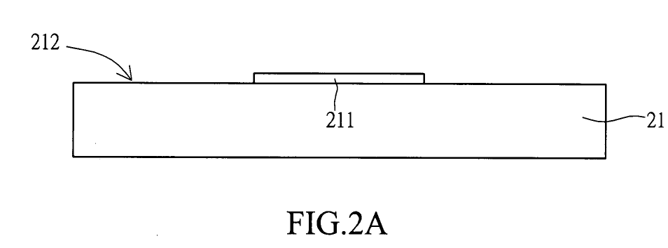

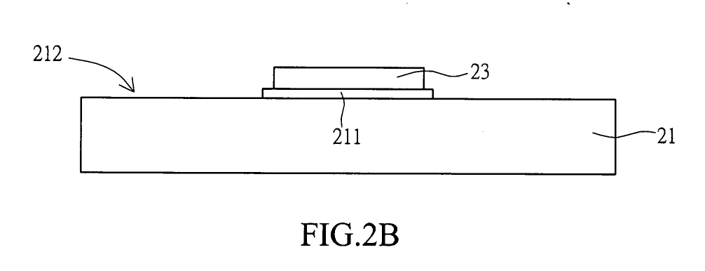

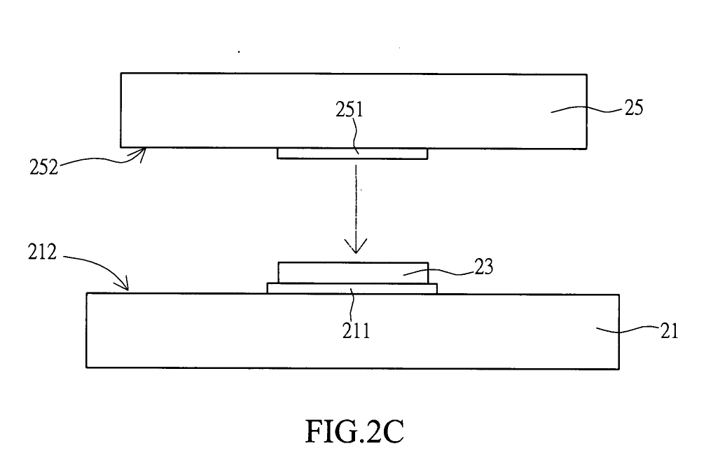

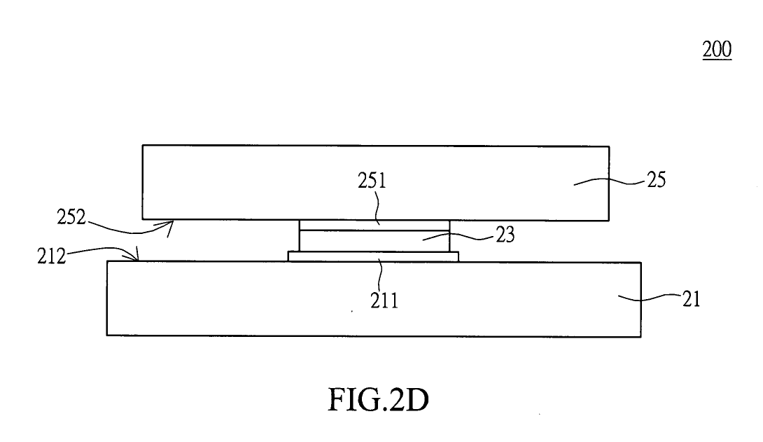

Referring to FIG. 2A to 2D, there are shown a schematic diagram of a flip chip packaging die attach process of a preferred embodiment of the present invention.

First, as shown in FIG. 2A, a carrier 21 is provided that is a lead frame or substrate, it comprises a lead pattern side 212, and an electrode 211 is disposed on the lead pattern side 212.

As shown in FIG. 2B, a block bump 23 is formed on the carrier 21, and the electrode 211 of carrier 21 contacts the block bump 23. The material of the block bump 23 is selected as an aluminum wire and/or ribbon, a gold wire and/or ribbon, or another wire and/or ribbon of a specific metal-type. Besides the block bump 23 formed on the electrode 211 by wedge bonding or ultrasonic bonding is completed by a metal wire/ribbon bonding technology which forms the metal diffusion happened in between the block bump 23 and the electrode 211.

As shown in FIG. 2C, a die 25 with an active side 252 is provided, a bond pad 251 is disposed on the active side 252, and the die 25 is a power transistor chip. Furthermore, flip the die 25, and then the bond pad 251 of the die 25 aligns with the block bump 23.

As shown in FIG. 2D, the bond pad 251 of the die 25 bonds to the block bump 23 such that the die 25 is attached to the carrier 21, and then a force and/or ultrasonic vibration apply on the die 25 to make the die 25 connected with the carrier 21 compactly. Besides, the force is generated by a thermal-sonic, thermal-compress or an ultrasonic-compress bonding technology. Therefore, the die 25 and the carrier 21 joint together to form the flip chip package structure 200, and the flip chip package structure 200 is a quad flat non-leaded package structure (QFN).

The block bump 23 of the present invention is formed by the wedge bonding technology, and therefore in bumping size and shapes can easily form larger bump than the ball bump (13) of the prior art, in which the die 25 is attached on the carrier 21 through a block bump 23 of larger size, so as to increase the compactness between the die 25 and the carrier 21, and avoid the die 25 disconnection form the carrier 21. Furthermore, the block bump 23 of larger size will reduce the contact resistance and increase the contact area between the die 25 and the carrier 21, so as to enhance the electrical performance and thermal dissipation performance of the flip-chip package structure 200 after it is packaged.

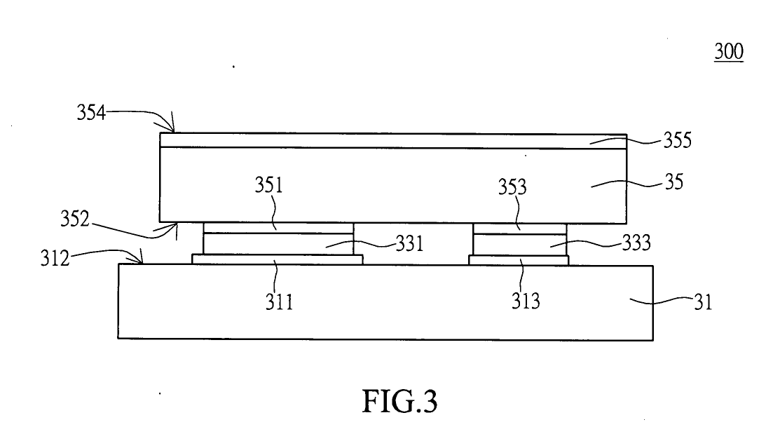

Referring to FIG. 3, there is shown a schematic diagram of the flip chip package structure of an embodiment of the present invention.

The flip-chip package structure 300 of the present invention is further applied in power transistor devices wherein the flip-chip (or semiconductor die itself) in the flip-chip package structure 300 could be a power transistor chip. In one embodiment the flip-chip package structure 300 is a quad flat non-leaded package structure (QFN).

The flip-chip package structure 300 comprises a carrier 31, a first block bump 331, a second block bump 333, and die 35.

Wherein the carrier 31 is a lead frame or substrate that comprises a lead pattern side 312, a first electrode pin 311 and a second electrode pin 313 are disposed on the lead pattern side 312. The first electrode pin 311 is a source pin, and the second electrode pin 313 is a gate pin.

The first block bump 331 and the second block bump 333 are respectively bonded to the first electrode pin 311 and the second electrode pin 313 of the carrier 31 by ultrasonic bonding or wedge bonding such that metal diffusion is happened between the block bumps 331/333 and the electrode pins 311/313. The material of the first block bump 331 and the second block bump 333 is selected as an aluminum wire and ribbon, a gold wire and ribbon, or another wire and ribbon of a specific metal-type. Besides, the first block bump 331 and the second block bump 333 are respectively formed on the first electrode pin 311 and the second electrode pin 313 by a wedge bonding technology.

The die 35 comprises an active side 352 and a backside 354, a first bond pad 351 and a second bond pad 353 are disposed on the active side 352, and an electrode layer 355 is disposed on said backside 354. The first bond pad 351 is a source electrode pad (aluminum material pad), the second bond pad 353 is a gate electrode pad (aluminum material pad), the electrode layer 355 is a drain electrode layer, and the size of the first bond pad 351 is larger than the size of the second bond pad 353.

The first bond pad 351 and the second bond pad 353 of the die 35 align with the first block bump 331 and the second block bump 333, then the first bond pad 351 and the second bond pad 353 of the die 35 are respectively bonded to the first block bump 331 and the second block bump 333 of carrier 31 by thermal-sonic bonding, thermal-compress bonding, or ultrasonic-compress bonding, and further a force and/or ultrasonic vibration apply on the die 35 to make the die 35 connected with the carrier 31 compactly. Similarly, the first block bump 331 and the second block bump 333 can be formed larger size by the wedge bonding technology, which increase the compactness between the die 35 and the carrier 31, so as to avoid the die 35 disconnection form the carrier 31. Furthermore, the first block bump 331 and the second block bump 333 of larger size will reduce the contact resistance and increase the contact area between the die 35 and the carrier 31, so as to enhance the electrical performance and thermal dissipation performance of the flip-chip package structure 300 after it is packaged.

Furthermore, the first block bump 331 and the second block bump 333 of the invention can be formed on the carrier 31 by using the existing metal ribbon bonding machine, therefore don't need to modify or regulate the machine, such as to reduce the production cost.

While this invention has been particularly shown and described with reference to the preferred embodiments thereof, it will be understood by those skilled in the art that various changes in form and details may be made without departing from the spirit and scope of the invention.

What is claimed is:

1. A flip chip package structure, comprising:
a carrier;
a block bump formed on said carrier; and
a die with a bond pad disposed thereon, wherein said bond pad of said die is bonded to said block bump of said carrier.

2. The flip-chip package structure of claim 1, wherein said carrier is a lead frame or substrate.

3. The flip-chip package structure of claim 1, wherein said carrier comprises an electrode contacting the block bump.

4. The flip-chip package structure of claim 1, wherein said block bump is formed by wedge bonding or ultrasonic bonding a metal wire or metal ribbon on said carrier.

5. The flip-chip package structure of claim 4, wherein the material of the block bump is aluminum or gold.

6. The flip-chip package structure of claim 1, wherein the die is a power transistor chip.

7. The flip-chip package structure of claim 1, wherein said bond pad of said die is bonded to said block bump of said carrier by thermal sonic bonding, thermal compress bonding, or ultrasonic compress bonding.

8. A flip chip package structure, comprising:
a carrier comprising a lead pattern side, and a first electrode pin and a second electrode pin disposed on said lead pattern side;
a first block bump and a second block bump respectively bonded to said first electrode pin and said second electrode pin by ultrasonic bonding or wedge bonding such that metal diffusion is happened between the block bumps and the electrode pins; and
a die comprising an active side and a backside, and a first bond pad and a second bond pad disposed on said active side;
wherein said first bond pad and said second bond pad of said die are respectively bonded to said first block bump and said second block bump of said carrier.

9. The flip-chip package structure of claim 8, wherein said first bond pad and said second bond pad of said die are respectively bonded to said first block bump and said second block bump of the carrier by thermal sonic bonding, thermal compress bonding, or ultrasonic compress bonding.

10. The flip-chip package structure of claim 8, wherein the material of said first block bump and said second block bump are selected as an aluminum wire and ribbon, a gold wire and ribbon, or another wire and ribbon of specified metal type.

11. The flip-chip package structure of claim 8, wherein said first bond pad is a source electrode pad.

12. The flip-chip package structure of claim 8, wherein said second bond pad is a gate electrode pad.

13. The flip-chip package structure of claim 8, wherein an electrode layer is disposed on said back side of said die, and said electrode layer is a drain electrode layer.

14. The flip-chip package structure of claim 8, wherein the die is a power transistor chip.

15. A die attach method of a flip chip package structure, comprising:
providing a carrier with a electrode and a die with a bond pad;
forming said block bump on said electrode; and
bonding said bond pad of said die to said block bump such that said die is attached to said carrier.

16. The die attach method of claim 15, wherein said block bump is formed on said electrode by wedge bonding or ultrasonic bonding a metal wire or metal ribbon.

17. The die attach method of claim 15, wherein the step of bonding the bond pad of the die to the block bump comprising:
aligning said bond pad of said die to said block bump; and
applying a force on said die to make said bond pad bonded to said block bump.

18. The die attach method of claim 17, wherein said force is generated by a thermal-sonic, thermal-compress or an ultrasonic-compress technology.
